(19) United States
(12) Patent Application Publication
(10) Pub. No.: US 2016/0307784 A1
(43) Pub. Date: Oct. 20, 2016

(54) SUBSTRATE PROCESSING SYSTEM

(71) Applicant: Tokyo Electron Limited, Tokyo (JP)

(72) Inventors: Satoshi GOMI, Yamanashi (JP); Daisuke MORISAWA, Yamanashi (JP); Keiji OSADA, Yamanashi (JP)

(21) Appl. No.: 15/133,110

(22) Filed: Apr. 19, 2016

(30) Foreign Application Priority Data
Apr. 20, 2015 (JP) 2015-085844

(51) Int. Cl. H01L 21/67; G05B 19/418; H01L 21/677

(52) U.S. Cl. CPC H01L 21/67276; H01L 21/67778; H01L 21/67766; H01L 21/67772; H01L 21/67769; G05B 19/41885; G05B 2219/45031

(57) ABSTRACT

A substrate processing system includes a processing unit having one or more processing chambers each of which includes a mounting table configured to mount thereon a substrate and is configured to perform predetermined processing on the substrate, a loading/unloading unit configured to load/unload a substrate container accommodating a plurality of substrates, one or more transfer units configured to transfer a substrate between the loading/unloading unit and the processing chambers, and a control unit configured to control the processing unit, the loading/unloading unit and the transfer units. The control unit controls a simulated operation, which does not include the predetermined processing in the processing chamber, to be performed on a plurality of dummy substrates in parallel. The simulated operation is a simulated transfer operation of the dummy substrates and includes a operation without transferring the dummy substrates from the loading/unloading unit into the processing chamber.

### CROSS-REFERENCE TO RELATED APPLICATIONS

This application claims priority to Japanese Patent Application No. 2015-085844 filed on Apr. 20, 2015, the entire contents of which is incorporated herein by reference.

### FIELD OF THE INVENTION

The disclosure relates to a substrate processing system for performing predetermined processing on a substrate such as a semiconductor wafer or the like.

### BACKGROUND OF THE INVENTION

In a semiconductor device manufacturing process, various processes, e.g., film formation, etching and the like, are repeatedly performed on a substrate such as a semiconductor wafer or the like. In a semiconductor manufacturing apparatus for performing such processes, a substrate processing system including a plurality of processing chambers is used. The substrate processing system further includes a loading/unloading unit for transferring a substrate to and from the outside, and one or more transfer units for transferring a substrate inside a system, e.g., between a plurality of processing chambers, and transferring a substrate to and from the outside.

In the substrate processing system, as the processing is repeated, reaction by-products are adhered and deposited on components in the processing chamber or on an inner wall of the processing chamber in which the processing such as film formation or the like is performed. The deposited by-products are peeled off to become particles, which may be adhered to the substrate to deteriorate a quality of a product. Particles may also be generated by operations of movable components of the substrate processing system which are provided to transfer the substrate.

As described above, particles are generated in the substrate processing system due to various reasons. In a conventional substrate processing system, in order to detect a particle generating source, a dummy substrate that is not subjected to actual processing is loaded into the processing chamber and transferred in simulation inside the system in the same sequence as that in the actual processing. For example, a plurality of dummy substrates is prepared. The dummy substrates are transferred from load ports into a plurality of processing chambers one at a time and returned to the load ports. By detecting the number of particles adhered to the respective dummy substrates, it is possible to specify the particle generating source among the processing chambers. This method can be performed by using a program referred to as a system recipe for performing the actual processing on the substrate. However, the simulated transfer using the system recipe is a sequential operation in which transfer of the dummy substrate into the processing chamber is required. Therefore, while the particle generating source can be specified if the particle generating source is any of the processing chambers, it is difficult to specify the particle generating source in, e.g., transfer routes from the load ports to the respective processing chambers.

In the substrate processing system, it is suggested to previously register various unit operations performed in the system separately from the system recipe, and allow the registered unit operations to be executed sequentially or parallelly by combining the unit operations (see, e.g., Japanese Patent Application Publication No. 2002-43290). This function is referred to as a maintenance macro.

The maintenance macro function disclosed in Japanese Patent Application Publication No. 2002-43290 has a high degree of freedom and thus can execute a plurality of unit operations performed in the substrate processing system separately or in combination with each other. Therefore, contents of the simulated transfer can be freely set, which is effective in specifying the particle generating source. However, the maintenance macro function allows simulated transfer of one dummy substrate inside the substrate processing system at a time. Accordingly, when various simulated transfer operations are preformed to specify the particle generating source by using the maintenance macro function, several tens of hours are required until the processing is completed. As a result, the downtime of the substrate processing system is increased.

The maintenance macro function is not provided for the processing of a substrate to be a product. Thus, a history of the simulated transfer is not left unlike the simulated transfer using the system recipe.

### SUMMARY OF THE INVENTION

In view of the above, the disclosure provides a substrate processing system capable of performing simulated transfer of a plurality of dummy substrates in parallel inside the system and also capable of performing simulated transfer that does not require transfer of a dummy substrate into the processing chamber.

In accordance with an aspect of the present invention, there is provided a substrate processing system including a processing unit having one or more processing chambers each of which includes a mounting table configured to mount thereon a substrate and is configured to perform predetermined processing on the substrate; a loading/unloading unit configured to load/unload a substrate container accommodating a plurality of substrates; one or more transfer units configured to transfer a substrate between the loading/unloading unit and the processing chambers; a control unit configured to control the processing unit, the loading/unloading unit and the transfer units. The control unit controls a simulated operation, which does not include the predetermined processing in the processing chamber, to be performed on a plurality of dummy substrates in parallel. The simulated operation is a simulated transfer operation of the dummy substrates and includes a operation without transferring the dummy substrates from the loading/unloading unit into the processing chamber.

### BRIEF DESCRIPTION OF THE DRAWINGS

The objects and features of the disclosure will become apparent from the following description of embodiments, given in conjunction with the accompanying drawings, in which:

FIG. 1 shows a schematic configuration of a substrate processing system;

FIG. 2 explains an exemplary hardware configuration of a control unit;

FIG. 3 is a functional block diagram showing a functional configuration of the control unit;

FIG. 4 is a flowchart showing a sequence of executing a simulated operation in each component of the substrate processing system under the control of the control unit;

FIG. 5 explains a typical example of a transfer route in a simulated transfer operation using a dummy substrate; and

FIG. 6 is a flowchart of exemplary steps of a method for detecting a particle generation source in the substrate processing system.

### DETAILED DESCRIPTION OF THE EMBODIMENTS

Hereinafter, embodiments will be described in detail with respect to the accompanying drawings.

(Outline of Substrate Processing System)

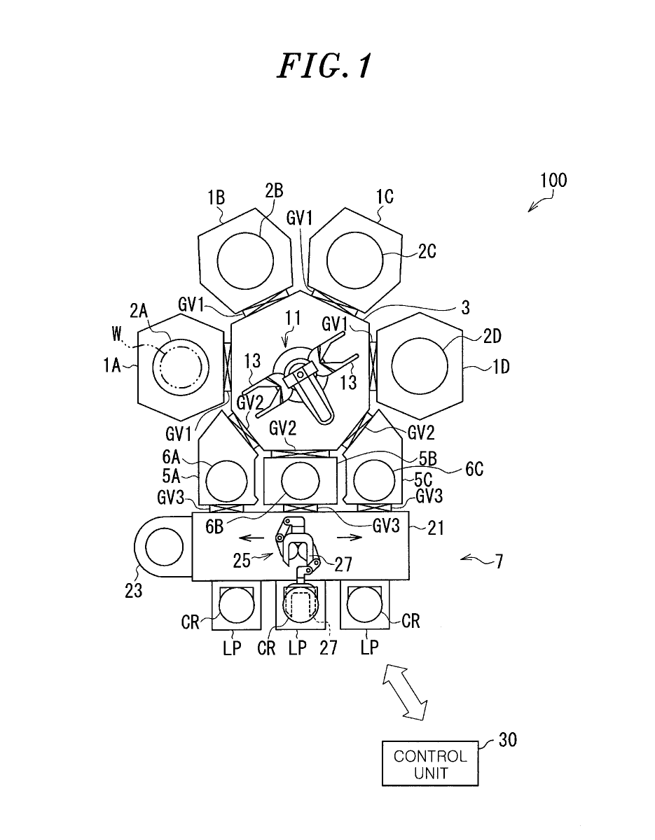

An outline of a substrate processing system according to an embodiment will be described with reference to FIG. 1. FIG. 1 shows a schematic configuration of a substrate processing system 1 configured to perform various processes, e.g., a film forming process, an etching process and the like, on a semiconductor wafer (hereinafter, simply referred to as “wafer”) as a substrate.

The substrate processing system 100 is configured as a cluster tool having a multi chamber structure. The substrate processing system 100 mainly includes four processing chambers 1A to 1D where various processes are performed on the wafer W, a vacuum side transfer chamber 3 connected to the processing chambers 1A to 1D via respective gate valves GV1, three load-lock chambers 5A to 5C connected to the vacuum side transfer chamber 3 via respective gate valves GV2, and a loader unit 7 connected to the three load-lock chambers 5A to 5C via respective gate valves GV3. The processing chambers 1A to 1D constitute a processing unit. The load-lock chambers 5A to 5C constitute a substrate delivery unit. The loader unit 7 constitutes a loading/unloading unit.

In the four processing chambers 1A to 1D (hereinafter, may be collectively referred to as “processing chamber 1”), a wafer W is subjected to a process, e.g., a CVD process, an etching process, an ashing process, a modification process, an oxidation process, a diffusion process or the like. In the processing chambers 1A to 1D, the wafer W may be subjected to the same process or different processes. Provided in the processing chambers 1A to 1D are processing stages 2A to 2D (hereinafter, may be collectively referred to as “processing stage 2”) serving as mounting tables for horizontally supporting the wafer W.

Although not illustrated, a plurality of support pins for holding and vertically moving the wafer W is provided at the processing stage 2 so as to be projected and retracted with respect to the mounting surface of the processing stage 2. The support pins are configured to be vertically displaced by an elevation mechanism and transfer the wafer W with respect to a vacuum side transfer unit 11 (to be described later) at a raised position.

Provided at the processing chamber 1 are a gas inlet unit (not shown) for introducing a processing gas, a cleaning gas, a cooling gas or the like and a gas exhaust unit (not shown) for performing vacuum evacuation.

Installed in the evacuable vacuum side transfer chamber 3 is the vacuum side transfer unit 11 for transferring the wafer W with respect to the processing chambers 1A to 1D or the load-lock chambers 5A to 5C. The vacuum side transfer unit 11 transfers the wafer W mounted on its forks 13 between the processing chambers 1A to 1D or between each of the processing chambers 1A to 1D and each of the load-lock chambers 5A to 5C. Loading/unloading openings (not shown) are respectively formed at side portions of the vacuum side transfer chamber 3 which correspond to the processing chambers 1A to 1D and the load-lock chambers 5A to 5C. In a state where the gate valves GV1 and GV2 are opened, the wafer W is loaded/unloaded through the loading/unloading openings.

The wafer W is transferred between the vacuum side transfer chamber 3 and an atmospheric side transfer chamber 21 (to be described later) via the load-lock chambers 5A to 5C that are vacuum preliminary chambers. Therefore, the load-lock chambers 5A to 5C are configured to be switched between a vacuum state and an atmospheric state. In the load-lock chambers 5A to 5C, standby stages 6A to 6C, each for mounting thereon the wafer W, are installed. The wafer W is transferred between the vacuum side transfer chamber 3 and the atmospheric side transfer chamber 21 via the standby stages 6A to 6C.

The loader unit 7 includes: a transfer chamber 21 open to an atmospheric pressure; three load ports LP provided adjacent to the transfer chamber 21; and an orienter 23 provided adjacent to a side of the transfer chamber 21, the orienter 23 serving as an orientation measurement device for measuring an orientation of the wafer W. In the transfer chamber 21, the atmospheric side transfer unit 25 for transferring the wafer W is installed. Each of the load ports LP can mount a wafer cassette CR thereon. The wafer cassette CR is configured to accommodate a plurality of wafers W arranged in multiple levels spaced at a regular interval.

The transfer chamber 21 open to an atmospheric pressure has a substantially rectangular shape when seen from the top. The atmospheric side transfer unit 25 is configured to be moved in the directions indicated by arrows in FIG. 1 by a driving mechanism (not shown). The atmospheric side transfer unit 25 transfers the wafer W mounted on the forks 27 between the wafer cassettes CR on the load ports LP, the load-lock chambers 5A to 5C, and the orienter 23.

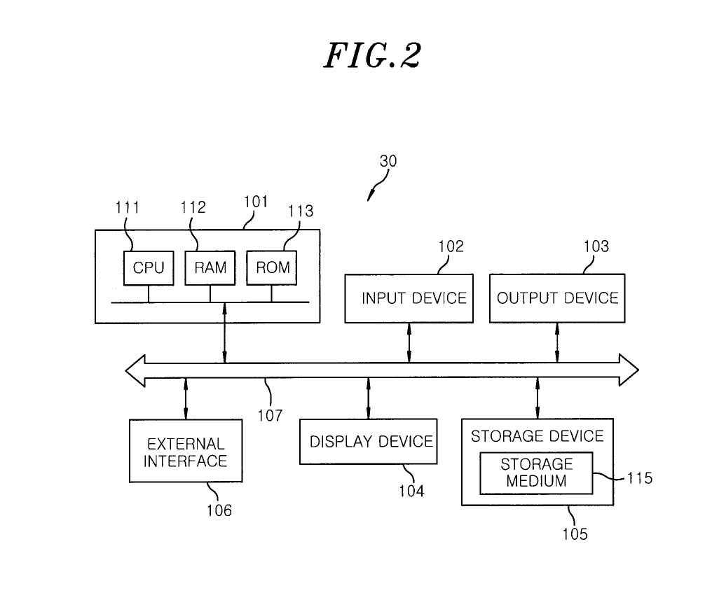

The components of the substrate processing system 100 are connected to and controlled by the control unit 30. Hereinafter, an exemplary hardware configuration of the control unit 30, i.e., an exemplary hardware configuration of the computer, will be described with reference to FIG. 2. The control unit 30 includes a main controller 101, an input device 102 such as a keyboard, a mouse or the like, an output device 103 such as a printer or the like, a display device 104, a storage device 105, an external interface 106, and a bus 107 connecting these components. The main controller 101 has a CPU (central processing unit) 111, a RAM 112, and a ROM 113. The storage device 105 is not limited to a specific storage device as long as it can store information. For example, the storage device 105 is a hard disc device or an optical disc device. Further, the storage device 105 is configured to store the information in a computer-readable storage medium 115 and read out the information from the storage medium 115. The storage medium 115 is not limited to a specific storage medium as long as it can store information. For example, the storage medium 115 is a hard disc or an optical disc. The storage medium 115 may be a storage medium that stores a program of the simulated operation of the present embodiment.

In the control unit 30, the CPU 111 executes a simulated operation control program stored in the ROM 113 or the storage device 105 while using the RAM 112 as a work area to function as a simulated operation control device.

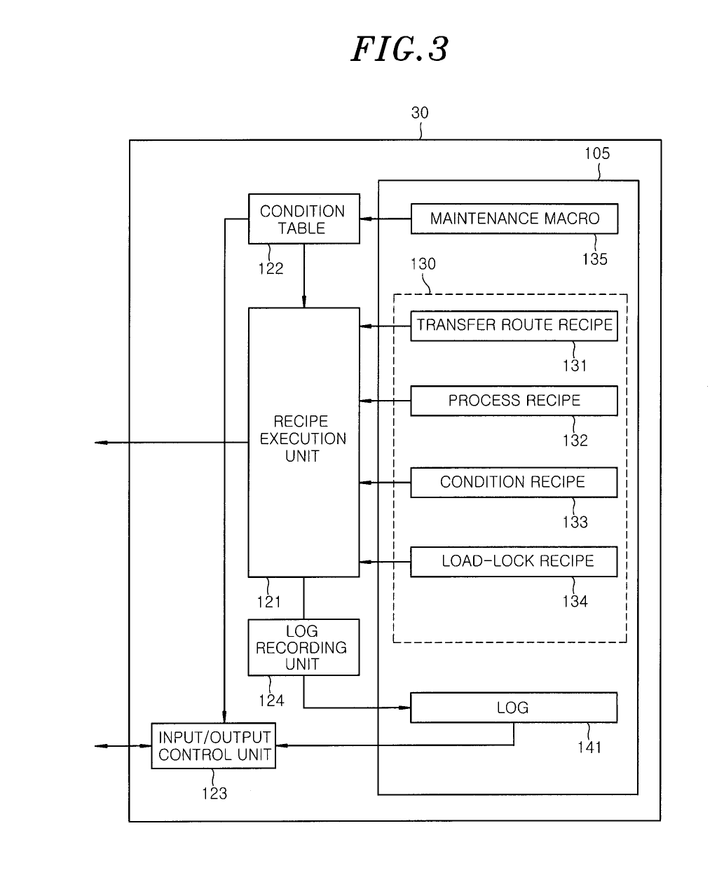

FIG. 3 is a functional block diagram showing a functional configuration of the control unit 30 functioning as the simulated operation control device. As shown in FIG. 3, the functional configuration of the control unit 30 includes a recipe execution unit 121, a condition table 122 as a maintenance macro setting unit, an input/output control unit 123, and a log recording unit 124 as a history recording unit. The CPU 111 executes the simulated operation control program stored in the ROM 113 or the storage device 105 while using the RAM 112 as the work area, thereby realizing the function as the simulated operation control device.

The recipe execution unit 121 executes the recipes in the substrate processing system 100 by reading out various recipes previously stored in the storage device 105 and transmitting control signals based on the recipes. In FIG. 3, the recipes stored in the storage device 105 include a transfer route recipe 131, a process recipe 132, a condition recipe 133, and a load-lock recipe 134. The transfer route recipe 131 is a recipe for setting a transfer route of the wafer W. The process recipe 132 is a recipe for setting various parameters (e.g., a pressure, a gas flow rate, a time, a sequence, and the like) in the processing chambers 1A to 1D. The condition recipe 133 is a recipe related to a process of adjusting conditions of the processing chambers 1A to 1D and a transfer system including the vacuum side transfer unit 11 and the atmospheric side transfer unit 25. The load-lock recipe 134 is a recipe related to processing of the wafer W in the load-lock chambers 5A to 5C, after the wafer W has been processed in the processing chambers 1A to 1D. These recipes may be collectively referred to as a “system recipe 130.” Although it is not illustrated, the substrate processing system 100 has a function of executing recipes other than these recipes.

The recipe execution unit 121 transmits a control signal such that the simulated operation is executed in the substrate processing system 100 by using both of the system recipe 130 and the maintenance macro 135 set by the condition table 122.

The storage device 105 also stores the maintenance macro 135. The maintenance macro 135 is a function of executing commands for the control system sequentially in a preset order or in parallel in order to perform maintenance for the transfer system including the processing chambers 1A to 1D, the vacuum side transfer unit 11, and the atmospheric side transfer unit 25. In other words, the maintenance macro 135 is obtained by previously registering a plurality of unit operations performed in the substrate processing system 100 and combining and storing the registered unit operation as a single macro (see Japanese Patent Application Publication No. 2002-43290).

The condition table 122 functions as a maintenance macro setting unit for selecting maintenance macros to be executed among the maintenance macros 135 stored in the storage device 105 and setting an execution condition therefor. The execution condition mainly includes timing and a condition. The timing is a timing of executing a selected maintenance macro, e.g., when a substrate is located at a specific part of a specific processing system. The condition is set depending on a state of each processing chamber, e.g., a condition that the processing chamber is empty for a predetermined period of time and/or a condition that a temperature is changed. The maintenance macro 135 set by the condition table 122 is controlled together with the system recipe 130 according to the control signal from the recipe execution unit 121. In the substrate processing system 100 of the present embodiment, it is possible to execute both of the maintenance macro 135 and the system recipe 130 by the function of the condition table 122.

The input/output control unit 123 controls input of the input device 102, output of the output device 103, display of the display device 104, and input/output of data with respect to the outside performed through the external interface 106.

The log recording unit 124 records a history of the simulated operation performed based on the system recipe 130 and the maintenance macro 135. The history recorded in the log recording unit 124 is stored as a log 141 in the storage device 105.

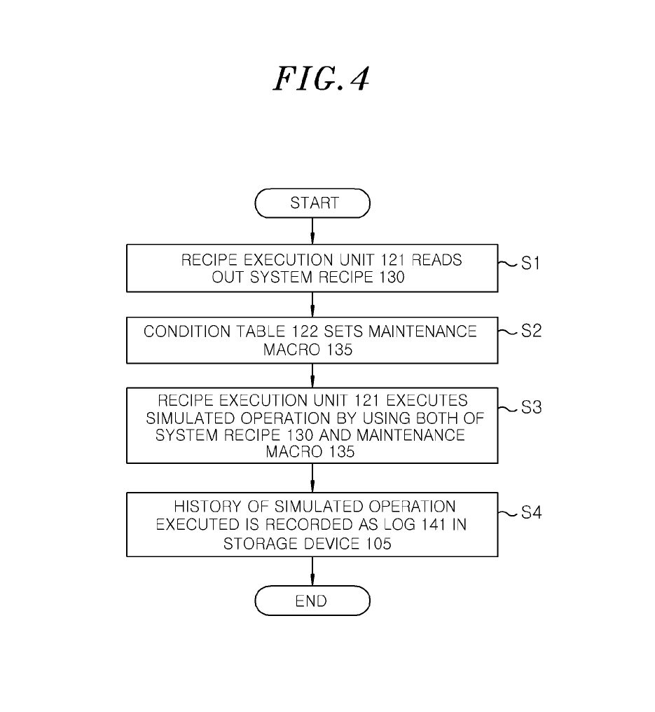

FIG. 4 is a flowchart showing a sequence of performing the simulated operation in each component of the substrate processing system 100 based on the simulated operation control program under the control of the control unit 30. The sequence includes steps S1 to S3.

(Step S1)

First, when an instruction for performing a simulated operation is inputted from the input device 102, for example, the simulated operation control program operates. In the step S1, the recipe execution unit 121 reads out the system recipe 130 stored in the storage device 105.

(Step S2)

Next, in a step S2, the condition table 122 sets the maintenance macro 135. In other words, the condition table 122 selects one or more maintenance macros to be executed among the maintenance macros 135 stored in the storage device 105 and sets execution conditions thereof. The type of the maintenance macro 135 executed in the step S2 may be determined by an input of a manager for the substrate processing system 100 through the input device 102. In this case, the condition table 122 is configured to receive an input signal from the input device 102, select one or more maintenance macros to be executed among the maintenance macros 135 stored in the storage device 105, and list up and display the selected maintenance macros 135 on a monitor screen of the display device 104.

(Step S3)

In a step S3, the recipe execution unit 121 executes the simulated operation in the substrate processing system 100 by using both of the system recipe 130 and the maintenance macro 135 set through the condition table 122. In other words, the recipe execution unit 121 executes the simulated operation of the dummy substrate based on the system recipe 130 and the maintenance macro 135 in the substrate processing system 100 by transmitting a control signal based on the system recipe 130 and the set maintenance macro 135.

the Sequence May Further Include a Following Step S4.

(Step S4)

In the step S4, the history of the simulated operation executed in the step S3 based on the system recipe 130 and the maintenance macro 135 is recorded by the log recording unit 124 and stored as the log 141 in the storage device 105.

With the above-described sequence and configuration of the control unit 30, the simulated operation of the dummy substrate can be performed by using both of the system recipe 130 and the maintenance macro 135. The simulated operation based on the system recipe 130 and the maintenance macro 135 can be performed on a plurality of dummy substrates in parallel according to the original function of the system recipe 130. Further, according to the original function of the system recipe 130, the history of the simulated operation performed by the system recipe 130 and the maintenance macro 135 can be stored as a log 141 in the storage device 105.

[General Processing Using System Recipe]

In the substrate processing system 100, a general processing is performed in a following sequence based on the system recipe 130. First, a single wafer W is unloaded from the wafer cassette CR by the atmospheric side transfer unit 25 and position-aligned by the orienter 23. Then, the wafer W is loaded into any one of the load-lock chambers 5A to 5C to be placed on any one of the standby stages 6A to 6C. Next, the wafer W in any one of the load-lock chambers 5A to 5C is transferred to any one of the processing chambers 1A to 1D by the vacuum side transfer unit 11 to be mounted on any one of the processing stages 2A to 2D and subjected to predetermined processing. After the processing, the wafer W is returned to the wafer cassette CR in the reversed sequence. In this manner, the processing of a single wafer W is completed.

[Simulated Operations]

Hereinafter, simulated operations in the substrate processing system 100 of the present embodiment will be described. As described above, in the substrate processing system 100, the simulated operations are performed based on the simulated operation control program under the control of the control unit 30. The simulated operations include, e.g., a simulated transfer operation of the vacuum side transfer unit 11 and/or the atmospheric side transfer unit 25, a simulated elevation operation of lifter pins (not shown) of the processing stages 2A to 2D, a simulated opening/closing operation of the gate valves GV1 to GV3, and the like. Here, as a representative example of the simulated operation, the simulated transfer operation of the vacuum side transfer unit 11 and/or the atmospheric side transfer unit 25 will be described by using a plurality of examples. However, the simulated operation is not limited to the following examples.

<Simulated Transfer Operation>

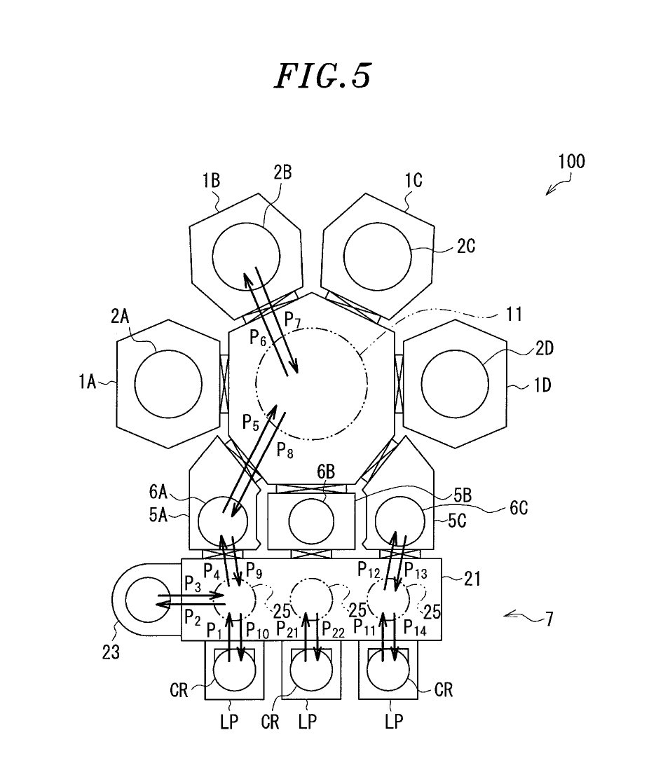

First, the simulated transfer operation will be described with reference to FIG. 5. FIG. 5 explains a typical example of a transfer route in the simulated transfer operation using a dummy substrate.

(Example 1 of Simulated Transfer Operation)

The routes P₁ to P₁₀ show the simulated transfer operation of the sequence including unloading of a single dummy substrate from the wafer cassette CR, loading of the dummy substrate into the processing chamber 1B, and returning of the dummy substrate to the wafer cassette CR.

The route P₁ shows a simulated transfer operation of unloading a single dummy substrate from the wafer cassette CR by the atmospheric side transfer unit 25. The route P₂ shows a simulated transfer operation of transferring the dummy substrate from the atmospheric side transfer unit 25 to the orienter 23.

The route P₃ shows a simulated transfer operation of unloading the dummy substrate from the orienter 23 by the atmospheric side transfer unit 25. The route P₄ shows a simulated transfer operation of transferring the dummy wafer to the standby stage 6A in the load-lock chamber 5A by the atmospheric side transfer unit 25.

The route P₅ shows a simulated transfer operation of unloading the dummy substrate from the standby stage 6A by the vacuum side transfer unit 11. The route P₆ shows a simulated transfer operation of transferring the dummy substrate to the processing stage 2B in the processing chamber 1B by the vacuum side transfer unit 11.

The route P₇ that is the reverse of the route P₆ shows a simulated transfer operation of transferring the dummy substrate from the processing stage 2B in the processing chamber 1B to the vacuum side transfer unit 11. The route P₈ that is the reverse of the route P₅ shows a simulated transfer operation of transferring the dummy substrate from the vacuum side transfer unit 11 to the standby stage 6A in the load-lock chamber 5A.

The route P₉ shows a simulated transfer operation of transferring the dummy substrate from the standby stage 6A to the atmospheric side transfer unit 25. The route P₁₀ is a simulated transfer operation of transferring the dummy substrate from the atmospheric side transfer unit 25 to the wafer cassette CR.

(Example 2 of Simulated Transfer Operation)

The routes P₁₁ to P₁₄ show the simulated transfer operation of the sequence including unloading of a single dummy substrate from the wafer cassette CR, loading of the dummy substrate into the load-lock chamber 5C, and returning of the dummy substrate to the wafer cassette CR. As shown by the routes P₁₁ to P₁₄, in the substrate processing system 100, simulated transfer that includes an operation without transferring the dummy substrate into the processing chambers 1A to 1D can also be performed.

First, the route P₁₁ shows a simulated transfer operation of unloading a single dummy substrate from the wafer cassette CR by the atmospheric side transfer unit 25. The route P₁₂ shows a simulated transfer operation of transferring the dummy substrate from the atmospheric side transfer unit 25 to, e.g., the standby stage 6C in the load-lock chamber 5C.

The route P₁₃ that is the reverse of the route P₁₂ shows a simulated transfer operation of transferring the dummy substrate from the standby stage 6C to the atmospheric side transfer unit 25. The route P₁₄ that is the reverse of the route P₁₁ shows a simulated transfer operation of transferring the dummy substrate from the atmospheric side transfer unit 25 to the wafer cassette CR.

In the substrate processing system 100 of the present embodiment, the simulated operation of the dummy substrate is performed by using both of the system recipe 130 and the maintenance macro 135 and thus has a high degree of freedom. Accordingly, it is possible to perform the simulated transfer operation that includes an operation without transferring the dummy substrate unloaded from the wafer cassette CR into any one of the processing chambers 1A to 1D as shown by the routes P₁₁ to P₁₄.

(Example 3 of Simulated Transfer Operation)

The routes P₂₁ to P₂₂ are examples of the simulated transfer operation in the loader unit 7. First, the route P₂₁ shows a simulated transfer operation of unloading a single dummy substrate from the wafer cassette CR by the atmospheric side transfer unit 25. The route P₂₂ shows a simulated transfer operation of returning the dummy substrate into the wafer cassette CR by the atmospheric side transfer unit 25.

In the substrate processing system 100, it is possible to perform a plurality of simulated transfer operations in parallel. Here, “in parallel” indicates that during a period in which a single preceding dummy substrate is unloaded from the wafer cassette CR and returned to the wafer cassette CR, a single or a plurality of subsequent dummy substrates is unloaded from the wafer cassette CR and transferred along the transfer route in the substrate processing system. For example, three dummy substrates are used at the same time and the simulated transfer operations indicated by the routes P₁ to P₁₀, the routes P₁₁ to P₁₄, and the routes P₂₁ to P₂₂ can be performed in parallel. In other words, in the substrate processing system 100 of the present embodiment, the simulated transfer operations of a plurality of dummy substrates can be carried out at the same time in the system as long as the dummy substrates do not collide with each other in any one of the processing chambers 1A to 1D, the load-lock chambers 5A to 5C, the vacuum side transfer unit 11, and the atmospheric side transfer unit 25. In that case, even if the routes of the simulated transfer operations of different dummy substrates are overlapped, the collision of the dummy substrates may be avoided by timing management.

All or a part of the simulated transfer operation may be repeated multiple times. For example, the simulated transfer operation indicated by the routes P₁ to P₁₀, which is a series of sequential operations, can be repeated multiple times. For example, among the simulated transfer operations indicated by the routes P₁ to P₁₀, the simulated transfer operation of transferring the dummy substrate to the processing stage 2B in the processing chamber 1B by the vacuum side transfer unit 11 which is indicated by the route P₆ and the simulated transfer operation of transferring the dummy substrate from the processing stage 2B of the processing chamber 1B to the vacuum side transfer unit 11 which is indicated by the route P₇ can be repeated multiple times. Although the simulated transfer operation in the loader unit 7 has been described in the example 3, it is also possible to perform a simulated transfer operation mainly including transfer of the dummy substrate between the processing chambers 1A to 1D or between the load-lock chambers 5A to 5C.

(Other Simulated Operations)

In the substrate processing system 100 of the present embodiment, the simulated elevation operation of the lifter pins (not shown) of the processing stages 2A to 2D and the simulated opening/closing operation of the gate valves GV1 to GV3, other than the above-described simulated transfer operation, can be performed once or repeated multiple times by the function of the maintenance macro 135. The simulated elevation operation and the simulated opening/closing operation can be performed regardless of existence/non-existence of the dummy substrate. For example, the simulated elevation operation or the simulated opening/closing operation can be performed even when the dummy substrate is not supported by the lifter pins or when the dummy substrate does not pass through the gate valves GV1 to GV3. The simulated elevation operation or the simulated opening/closing operation can be performed in combination with or in parallel with the simulated transfer operation. Types of the simulated operation vary depending on the configuration of the substrate processing system and are not limited to the simulated operations described above.

(Method for Detecting Particle Generating Source)

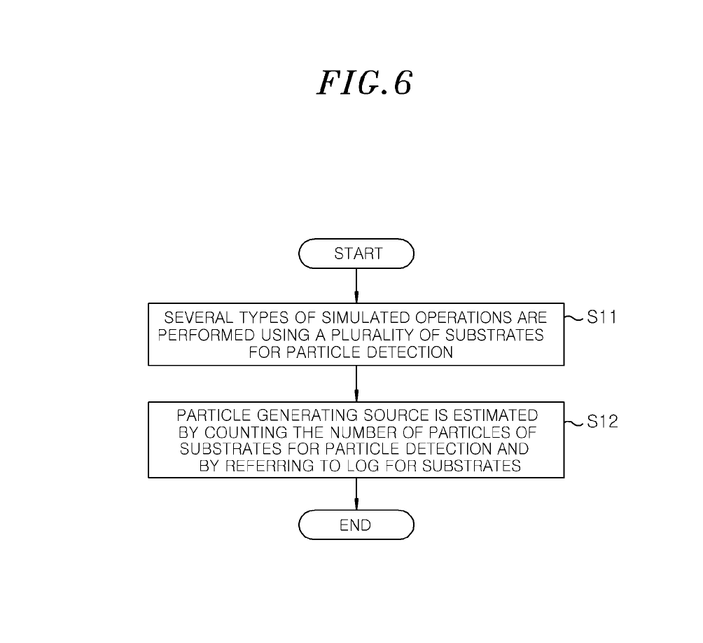

Hereinafter, a method for detecting a particle generating source in the substrate processing system 100 will be described with reference to FIG. 6. FIG. 6 is a flowchart showing exemplary steps of the method for detecting a particle generating source.

First, in a step S11, several types of simulated operations are performed using a plurality of substrate for particle detection instead of the dummy substrate. Further, after the simulated elevation operations or the simulated opening/closing operations are performed, the simulated transfer operation may be performed by using the substrates for particle detection. In the substrate processing system 100, as described above, the simulated transfer operation can be performed on the substrates for particle detection in parallel. Therefore, the time required for the step S11 can be considerably reduced compared to that in the conventional method using the maintenance macro only.

Next, in a step S12, the particle generating source is estimated by counting the number of particles of the substrates for particle detection which have been subjected to the simulated operation. In the substrate processing system 100, as described above, it is possible to perform the simulated transfer operation that includes an operation without transferring the dummy substrate into any one of the processing chambers 1A to 1D and also possible to repeat the transfer along a specific route or repeat the simulated elevation operation or the simulated opening/closing operation. Therefore, the particle generating source can be easily estimated compared to the case of performing the simulated transfer operation of the sequence using the system recipe only. Since the particle generating source is estimated by referring to the log 141 recorded by the log recording unit 124, it is possible to easily confirm a step of the simulated operation in which the particle adhesion has occurred.

As described above, in the substrate processing system 100, the simulated transfer of a plurality of dummy substrates can be performed in parallel by performing the simulated operation of the dummy substrates while using both of the system recipe 130 and the maintenance macro 135. Further, the simulated transfer that includes transferring the dummy substrates into the processing chambers 1A to 1D can be performed. The history of the simulated operation can be stored as the log 141. Therefore, in the case of performing the simulated operation of the dummy substrates for the purpose of specifying the particle generating source, the substrate processing system 100 can easily specify the particle generating source. Further, the time required until the simulated operation is completed can be considerably reduced.

The disclosure is not limited to the above embodiment and may be variously modified. For example, the disclosure is not limited to the substrate processing system 100 having the configuration shown in FIG. 1 and may also be applied to other substrate processing systems of various configurations. A substrate that is a processing target of the substrate processing system is not limited to a wafer W for manufacturing a semiconductor device and may also be, e.g., a glass substrate for flat panel display, a substrate for manufacturing a solar cell panel, or the like.

The simulation operation in the substrate processing system 100 may also be used for, e.g., running of the apparatus for reliability test or the like, in addition to the detection of the particle generating source.

While the disclosure has been shown and described with respect to the embodiments, it will be understood by those skilled in the art that various changes and modifications may be made without departing from the scope of the disclosure as defined in the following claims.

What is claimed is:

1. A substrate processing system comprising:
a processing unit including one or more processing chambers each of which includes a mounting table configured to mount thereon a substrate and is configured to perform predetermined processing on the substrate;
a loading/unloading unit configured to load/unload a substrate container accommodating a plurality of substrates;
one or more transfer units configured to transfer a substrate between the loading/unloading unit and the processing chambers; and
a control unit configured to control the processing unit, the loading/unloading unit and the transfer units,
wherein the control unit controls a simulated operation, which does not include the predetermined processing in the processing chamber, to be performed on a plurality of dummy substrates in parallel, and
wherein the simulated operation is a simulated transfer operation of the dummy substrates and includes a operation without transferring the dummy substrates from the loading/unloading unit into the processing chamber.

2. The substrate processing system of claim 1, further comprising a substrate delivery unit disposed between the processing unit and the loading/unloading unit,
wherein the transfer units include:
a first transfer unit configured to transfer the substrate inside the loading/unloading unit and between the loading/unloading unit and the substrate delivery unit; and
a second transfer unit configured to transfer the substrate between the substrate delivery unit and the processing chamber, and
wherein the simulated operation includes:
a simulated transfer operation of transferring the dummy substrate from the loading/unloading unit to the second transfer unit through the first transfer unit and the substrate delivery unit, and
a simulated transfer operation of transferring the dummy substrate from the second transfer unit to the loading/unloading unit through the substrate delivery unit and the first transfer unit.

3. The substrate processing system of claim 2, wherein the simulated operation includes:
a simulated transfer operation of transferring the dummy substrate from the loading/unloading unit into the processing chamber through the first transfer unit, the substrate delivery unit, and the second transfer unit; and
a simulated transfer operation of transferring the dummy substrate from the processing chamber to the loading/unloading unit through the second transfer unit, the substrate delivery unit, and the first transfer unit.

4. The substrate processing system of claim 1, wherein the simulated operation includes a simulated transfer operation of the substrate in the loading/unloading unit.

5. The substrate processing system of claim 1, wherein the simulated transfer operation includes repeatedly executing all or a part of sequential operations.

6. The substrate processing system of claim 1, wherein the mounting table includes a plurality of lifter pins for transferring a substrate with respect to the transfer unit, and
wherein the simulated operation includes a simulated elevation operation of the lifter pins in a state where no substrate is transferred.

7. The substrate processing system of claim 1, wherein the processing chamber includes an opening through which a substrate is loaded and unloaded, and a gate valve configured to keep the processing chamber in a vacuum state by sealing the opening, and
wherein the simulated operation includes a simulated opening/closing operation of the gate valve in a state where no substrate passes through the opening.

8. The substrate processing system of claim 1, wherein the control unit includes:
a storage unit configured to store a maintenance macro for combining and executing a plurality of previously registered unit operations and a system recipe for performing the predetermined processing in the processing chamber;
a recipe execution unit configured to read out and execute the system recipe;
a maintenance macro setting unit configured to set a maintenance macro to be controlled by the recipe execution unit together with the system recipe; and
a history recording unit configured to record a history of the simulated operation, and
wherein the control unit controls the recipe execution unit to read out the system recipe, the maintenance macro setting unit to set the maintenance macro, and the recipe execution unit to perform the simulated operation by using both of the system recipe and the maintenance macro set by the maintenance macro setting unit.

9. The substrate processing system of claim 1, wherein the simulated operation is performed to detect particles.
